(19) United States
(12) Patent Application Publication
(10) Pub. No.: US 2014/0145216 A1
(43) Pub. Date: May 29, 2014

(54) LED WITH WIRE SUPPORT

(71) Applicant: ADVANCED OPTOELECTRONIC TECHNOLOGY, INC., (US)

(72) Inventors: LUNG-HSIN CHEN, Hsinchu (TW); PIN-CHUAN CHEN, Hsinchu (TW); WEN-LIANG TSENG, Hsinchu (TW)

(73) Assignee: ADVANCED OPTOELECTRONIC TECHNOLOGY, INC., Hsinchu Hsien (TW)

(21) Appl. No.: 13/859,739

(22) Filed: Apr. 10, 2013

(30) Foreign Application Priority Data
Nov. 27, 2012 (CN) 201210490083.8

(51) Int. Cl. H01L 33/62; H01L 27/15

(52) U.S. Cl. CPC H01L 33/62; H01L 27/15
USPC 257/88

(57) ABSTRACT

An LED includes a base, a first chip and a second chip mounted on the base, a wire support formed on the base, and wires electrically connecting the first chip and the second chip with the base. The base includes a first lead, a second lead and an insulative band connecting the first lead and the second lead. A first wire connects an electrode of the first chip to the wire support, and a second wire connects an electrode of the second chip to the wire support. The first wire and the second wire are electrically connected to each other via a conductive layer formed on the wire support. The wire support in one embodiment is a Zener diode.

### BACKGROUND

1. Technical Field

The present disclosure relates to an LED (light-emitting diode), and more particularly, to an LED have a wire support for connecting wires which are used to electrically connect different LED chips of the LED.

2. Description of Related Art

As a new type of light source, LEDs are widely used in various applications. Some LEDs have elongated shapes to meet particular requirements. A long LED generally includes multiple chips arranged in a line for producing a linear light band. Every two adjacent chips are electrically connected to each other via a wire. Since a distance between the two chips is long, the wire is required to be made long enough to connect the two chips. However, during bonding of the long wire to the two chips, the wire is prone to collapse due to a too large weight thereof. Normal electrical connection of the chips may be affected by such collapse of the long wire. Furthermore, the long wire may have a large height when curvedly connecting the two chips. Thus, a thickness of the LED is also increased by the height of the connecting wire.

What is needed, therefore, is an LED with a wire support which can overcome the limitations described above.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a top view of an LED in accordance with a first embodiment of the present disclosure.

FIG. 2 is a cross section of the LED of FIG. 1 taken along line II-II thereof.

FIG. 3 is an enlarged view of a wire support of the LED of FIG. 2.

FIG. 4 is a top view of the wire support of FIG. 3.

FIG. 5 is a top view of an LED in accordance with a second embodiment of the present disclosure.

FIG. 6 is a cross section of the LED of FIG. 5 taken along line VI-VI thereof.

FIG. 7 is an enlarged view of a wire support of the LED of FIG. 5.

FIG. 8 is a top view of the wire support of FIG. 7.

### DETAILED DESCRIPTION OF THE EMBODIMENTS

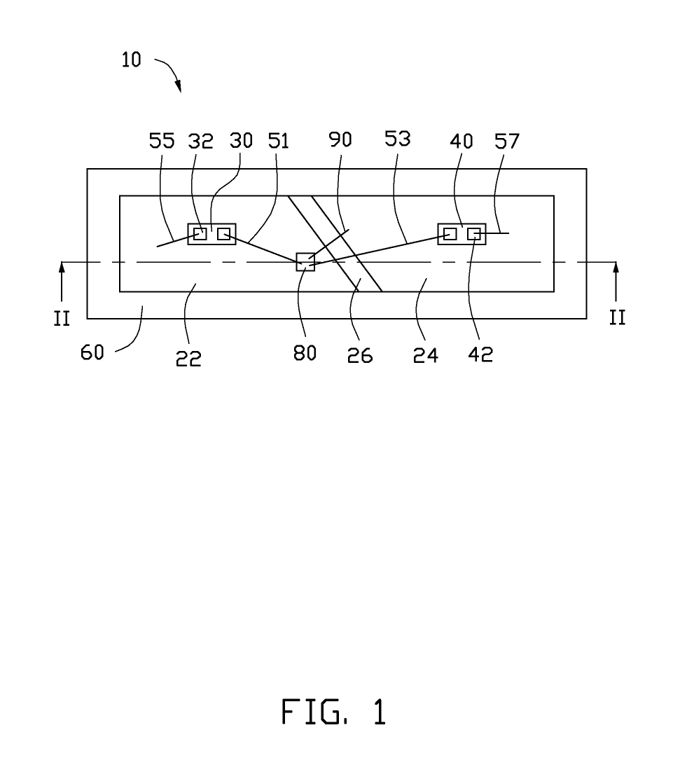

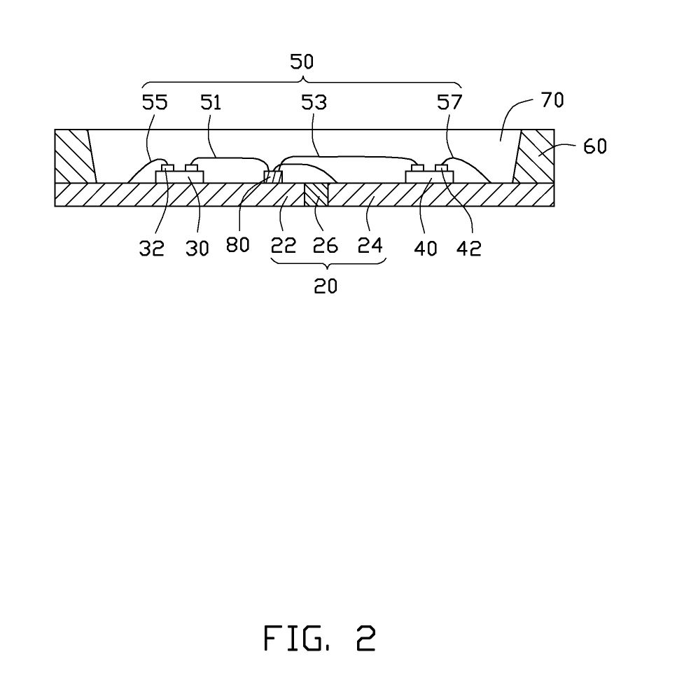

Referring to FIGS. 1-2, an LED 10 in accordance with a first embodiment of the present disclosure is shown. The LED 10 includes a base 20, a sidewall 60 extending upwardly from the base 20, a first chip 30 and a second chip 40 mounted on the base 20, a first wire 51, a second wire 53, a third wire 55 and a fourth wire 57 connecting the first chip 30 and the second chip 40 with the base 20, and an encapsulant 70 sealing the first chip 30 and the second chip 40.

The base 20 includes a first lead 22, a second lead 24 and an insulative band 26 connecting the first lead 22 and the second lead 24. The first lead 22 and the second lead 24 may be made of metal such as copper or aluminum. Each of the first lead 22 and the second lead 24 has a trapezoid shape. The insulative band 26 electrically insulates the first lead 22 from the second lead 24 to prevent direct electrical connection between the first lead 22 and the second lead 24. The insulative band 26 is inclined relative to a long side of the base 20. The sidewall 60 is attached to a circumferential area of a top face of the base 20. The sidewall 60 has an inclined inner circumferential face for reflecting light emitted from the first chip 30 and the second chip 40 upwardly.

The first chip 30 and the second chip 40 are respectively fixed to the first lead 22 and the second lead 24. Both the first chip 30 and the second chip 40 are made of semiconductor materials such as GaN, InGaN or AlInGaN. In this embodiment, the first chip 30 and the second chip 40 can emit blue light when being activated. The first chip 30 and the second chip 40 are arranged in a line parallel to the long side of the base 20. The insulative band 26 is located between the first chip 30 and the second chip 40. Each of the first chip 30 and the second chip 40 has two electrodes 32, 42 located a top thereof, wherein a right electrode 32 of the first chip 30 is connected to the first wire 51, a left electrode 32 of the first chip 30 is connected to the third wire 55, a left electrode 42 of the second chip 40 is connected to the second wire 53, and a right electrode 42 of the second chip 40 is connected to the fourth wire 57. The third wire 55 connects the left electrode 32 of the first chip 30 to the first lead 22, and the fourth wire 57 connects the right electrode 42 of the second chip 40 to the second lead 24. Alternatively, if the two electrodes 32, 42 of each of the first chip 30 and the second chip 40 are located at the top and a bottom thereof, the third wire 55 and the fourth wire 57 may be omitted since the bottom electrodes 32, 42 of the first chip 30 and the second chip 40 can directly connect the first lead 22 and the second lead 24, respectively.

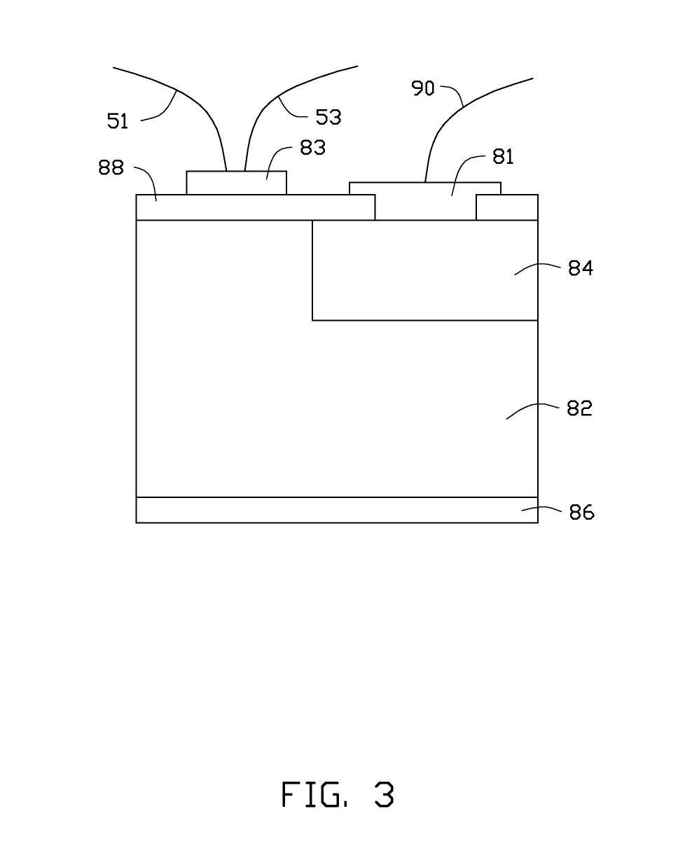

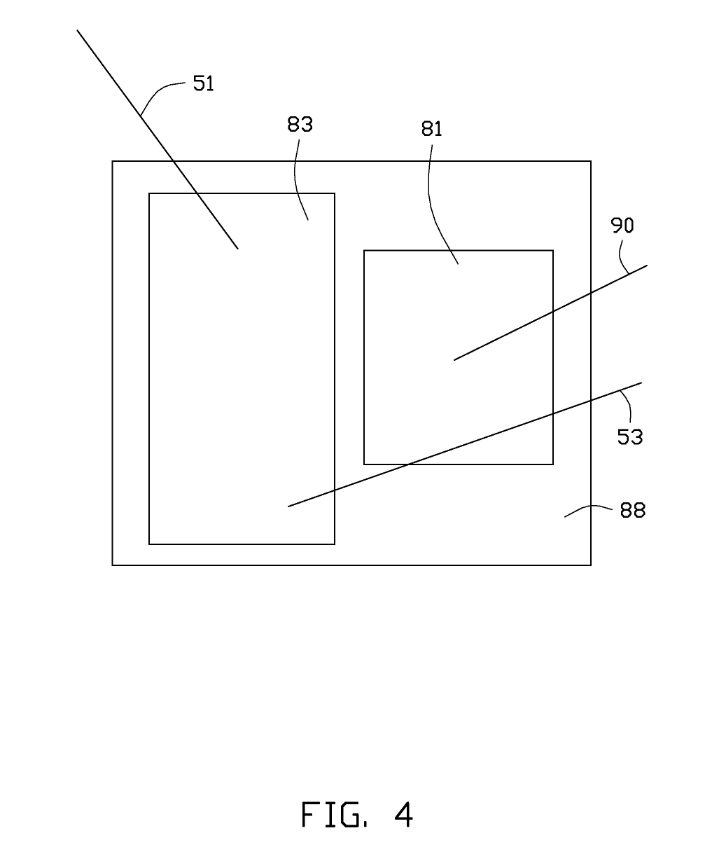

Also referring to FIGS. 3-4, a wire support 80 is attached on a top face of the first lead 22. A distance between the first chip 30 and the second chip 40 is larger than that between the first chip 30 and the wire support 80, and that between the second chip 40 and the wire support 80. The wire support 80 is deviated from the line defined by the first chip 30 and the second chip 40. In this embodiment, the wire support 80 includes a Zener diode which can protect the first chip 30 and the second chip 40 from damage by static. The Zener diode includes a P-type layer 84 and an N-type layer 82. The N-type layer 82 defines a groove in a top face thereof. The P-type layer 84 is totally received in the groove with a top face thereof being flush with that of the N-type layer 82. A connecting layer 86 connects a bottom face of the N-type layer 82 with the top face of the first lead 22. The connecting layer 86 is electrically conductive to conduct the N-type layer 82 with the first lead 22. An insulation layer 88 is formed on a top of the Zener diode. The insulation layer 88 covers a whole top face of the N-type layer 82 and a part of a top face of the P-type layer 84. A through hole (not labeled) is defined in the insulation layer 88 to expose another part of the P-type layer 84. An electrical pad 81 is formed on the insulation layer 88. The electrical pad 81 extends through the through hole to join the exposed part of the P-type layer 84. A conductive wire 90 connects the electrical pad 81 with the second lead 24 so that the Zener diode can be powered through the first lead 22 and the second lead 24.

A conductive layer 83 is formed on a top face of the insulation layer 88, avoiding the electrical pad 81. The first wire 51 and the second wire 53 are connected to the conductive layer 83 to be in electrical connection with each other. Thus, the first chip 30 and the second chip 40 are in serial connection by the first wire 51 and the second wire 53. Since the wire support 80 acts as an interconnection of the two separate first wire 51 and second wire 53, a long wire is not required to connect the first chip 30 and the second chip 40. Thus, problems induced by the long wire, such as collapse or large height, are prevented for the LED 10. Accordingly, the LED 10 can be made thin enough.

The encapsulant 70 seals the first chip 30, the second chip 40, the first wire 51, the second wire 53, the third wire 55, the fourth wire 57 and the conduction wire 90 for isolating them from an outside environment. The encapsulant 70 may be made of transparent materials such as silicone, glass, epoxy or the like. Alternatively, phosphors (not visible) may be further doped in the encapsulant 70 to change color of the light emitted from the first chip 30 and the second chip 40.

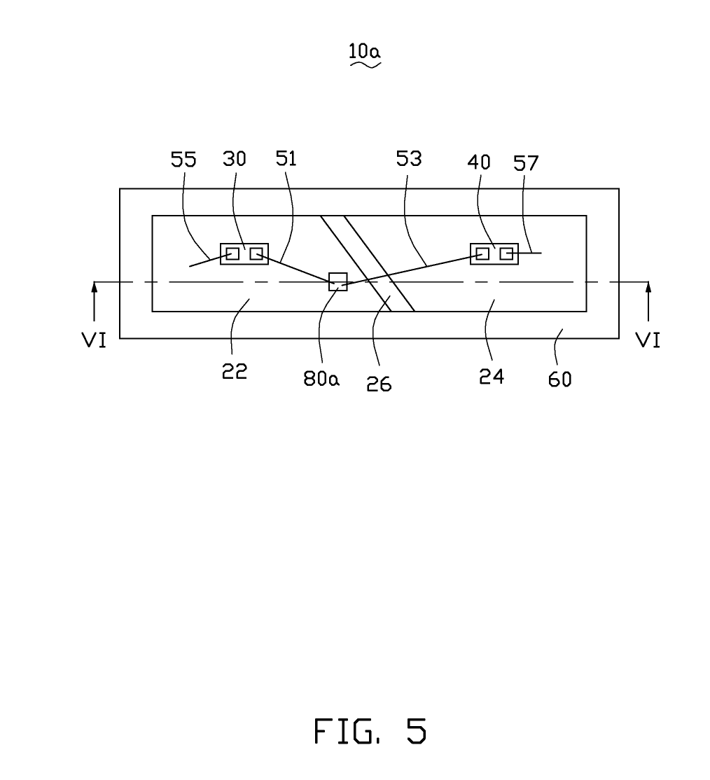

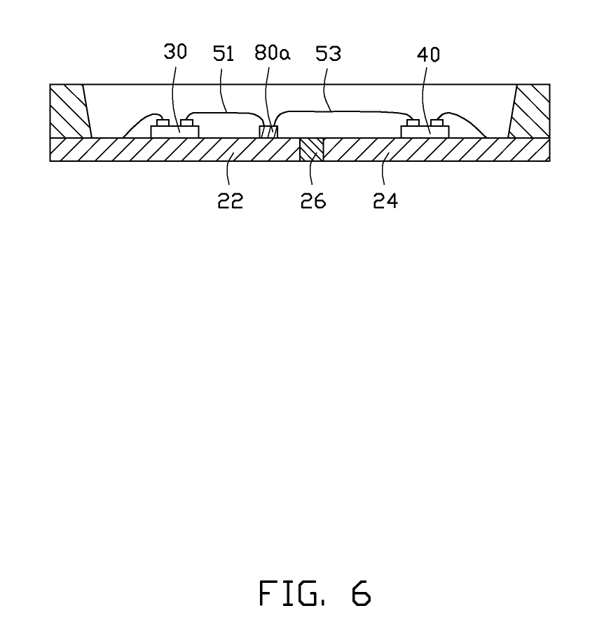

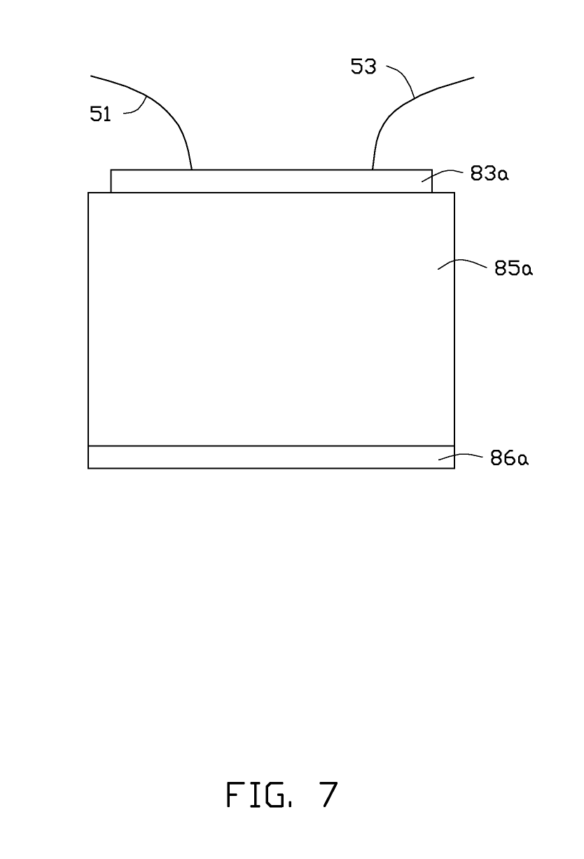

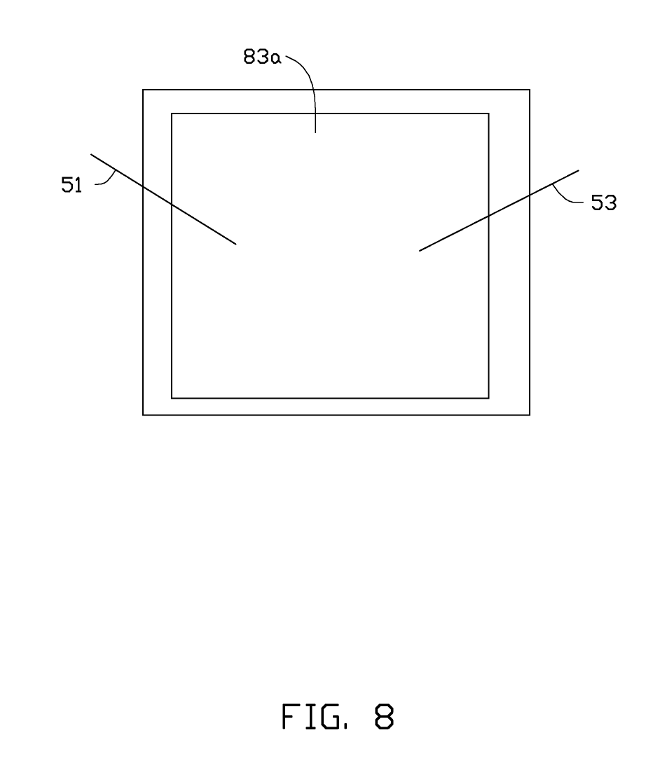

The Zener diode of the wire support 80 may be replaced by other structures. For example, an LED 10a shown in FIGS. 5-8 uses an insulating block 85a substituting the Zener diode. The insulating block 85a is attached on the top face of the first lead 22 by a connecting layer 86a. The connecting layer 86a may be electrically conductive or insulative. A conductive layer 83a is formed on a top face of the insulating block 85a to connect the first wire 51 and the second wire 53. Furthermore, in an alternative embodiment, the insulating block 85a may be integrally protruded upwardly from a top face of the insulative band 26. Thus, the connecting layer 86a is not desired to bond the insulating block 85a to the first lead 22.

It is believed that the present disclosure and its advantages will be understood from the foregoing description, and it will be apparent that various changes may be made thereto without departing from the spirit and scope of the present disclosure or sacrificing all of its material advantages, the examples hereinbefore described merely being preferred or exemplary embodiments.

What is claimed is:

1. An LED (light emitting diode) comprising:
a base;
a first chip and a second chip mounted on the base;
a wire support fixed on the base, a distance between the first chip and the second chip being larger than a distance between the first chip and the wire support, and a distance between the second chip and the wire support;
a first wire connecting the first chip to the wire support; and
a second wire connecting the second chip to the wire support;
wherein the first wire and the second wire are electrically connected by a conductive layer formed on the wire support.

2. The LED of claim 1, wherein the base comprises a first lead, a second lead and an electrically insulative band connecting the first lead and the second lead.

3. The LED of claim 2, wherein the wire support is attached on the base via a connecting layer.

4. The LED of claim 3, wherein the wire support comprises a Zener diode.

5. The LED of claim 4, wherein the Zener diode comprises an N-type layer defining a groove and a P-type layer received in the groove, a bottom face of the N-type layer being connected to the connecting layer.

6. The LED of claim 5, wherein a top face of the P-type layer is flush with a top face of the N-type layer.

7. The LED of claim 5, wherein the Zener diode further comprises an insulation layer covering the P-type layer and the N-type layer, the conductive layer being directly formed on the insulation layer.

8. The LED of claim 7, wherein the Zener diode further comprises an electrical pad extends through the insulation layer and connecting the P-type layer, the electrical pad being spaced from the conductive layer.

9. The LED of claim 8, wherein the bottom face of the N-type layer of the Zener diode is electrically connected to the first lead by the conductive layer, and the electrical pad is electrically connected to the second lead via a conduction wire.

10. The LED of claim 3, wherein the wire support comprises an insulating block fixed to the first lead via the connecting layer.

11. The LED of claim 2, wherein the wire support comprises an insulating block protruding upwardly from the insulative band.

12. The LED of claim 11, wherein the insulating block and the insulative band are made of a single monolithic piece of a material.

13. The LED of claim 1, wherein the first chip and the second chip are arranged in a line parallel to a long side of the base, the wire support being deviated from the line defined by the first chip and the second chip.

14. The LED of claim 13, wherein the insulative band is inclined relative to the line defined by the first chip and the second chip.

15. The LED of claim 1, wherein the first chip and the second chip emit light having the same color.

16. The LED of claim 2, wherein the first chip is fixed on the first lead, and the second chip is fixed on the second lead.

17. The LED of claim 2, wherein the first chip is electrically connected to the first lead via a third wire, and the second chip is electrically connected to the second lead via a fourth wire.
